(19) United States
(12) Patent Application Publication
(10) Pub. No.: US 2025/0169080 A1
(43) Pub. Date: May 22, 2025

(54) VERTICAL MEMORY DEVICE

(71) Applicant: SAMSUNG ELECTRONICS CO., LTD., SUWON-SI (KR)

(72) Inventors: Bonjae KOO, Suwon-si (KR); Seulji SONG, Suwon-si (KR); Youngsun SONG, Suwon-si (KR)

(21) Appl. No.: 18/924,249

(22) Filed: Oct. 23, 2024

(30) Foreign Application Priority Data
Nov. 20, 2023 (KR) 10-2023-0160385

(51) Int. Cl. H10B 63/00; H01L 23/00; H01L 25/065; H01L 25/18; H10B 80/00

(52) U.S. Cl. CPC H10B 63/24; H01L 24/08; H01L 25/0657; H01L 25/18; H10B 80/00; H01L 2224/08145; H01L 2924/1431; H01L 2924/1443

(57) ABSTRACT

A vertical memory device includes a substrate; a stack structure comprising a plurality of isolation insulating layers and a plurality of word line plates which are alternately stacked on the substrate along a vertical direction; and a plurality of electrode structures disposed on the substrate. Each of the plurality of electrode structures includes a single-crystal silicon filler extending on the substrate along the vertical direction, penetrating the plurality of isolation insulating layers and the plurality of word line plates, and contacting the substrate; and a plurality of variable resistance layers spaced apart from each other along the vertical direction, and partially covering a sidewall of the single-crystal silicon filler. Each variable resistance layer is arranged between the single-crystal silicon filler and two of the word line plates.

### CROSS-REFERENCE TO RELATED APPLICATION

This application is claims priority under 35 U.S.C. § 119 to Korean Patent Application No. 10-2023-0160385, filed on Nov. 20, 2023, in the Korean Intellectual Property Office, the disclosure of which is incorporated by reference herein in its entirety.

### 1. TECHNICAL FIELD

The inventive concept relates to a memory device, and more particularly, to a vertical memory device including a plurality of memory cells stacked in a vertical direction.

### 2. DESCRIPTION OF THE RELATED ART

As the demand for miniaturization, multifunctionality, and high performance of electronic devices rises, there is a need for high-capacity semiconductor memory devices. An increased integration level of semiconductor memory devices provides high capacities. The current level of integration in two-dimensional (2D) semiconductor memory devices is primarily dictated by the space required for each unit memory cell. And the advancement in integration for these 2D semiconductor memory devices has been limited. Accordingly, a 3D semiconductor memory device has been suggested in which a plurality of memory cells are stacked on a substrate in a vertical direction that increases the memory capacity.

### SUMMARY

The inventive concept provides a vertical memory device with improved electrical characteristics and reliability.

According to an aspect of the inventive concept, a vertical memory device includes a substrate; a stack structure comprising a plurality of isolation insulating layers and a plurality of word line plates which are alternately stacked on the substrate along a vertical direction; and a plurality of electrode structures disposed on the substrate. Each of the plurality of electrode structures includes a single-crystal silicon filler extending on the substrate along the vertical direction, penetrating the plurality of isolation insulating layers and the plurality of word line plates, and contacting the substrate; and a plurality of variable resistance layers spaced apart from each other along the vertical direction, and partially covering a sidewall of the single-crystal silicon filler. Each variable resistance layer is arranged between the single-crystal silicon filler and two of the word line plate.

According to another aspect of the inventive concept, a vertical memory device includes a single-crystal silicon substrate; a plurality of single-crystal silicon fillers that are repeatedly disposed along a first horizontal direction and a second horizontal direction and extend along a vertical direction, wherein an end portion of each of the plurality of single-crystal silicon fillers along the vertical direction is connected to the single-crystal silicon substrate, and wherein the first horizontal direction and the second horizontal direction cross each other; a plurality of word line plates that are spaced apart from each other on the single-crystal silicon substrate along the vertical direction, overlap each other along the vertical direction, and at least partially surround a portion of a sidewall of each of the plurality of single-crystal silicon fillers; and a plurality of ovonic threshold switching (OTS) material layers respectively disposed between the plurality of single-crystal silicon fillers and the plurality of word line plates, wherein the OTS material layer are spaced apart from each other along the vertical direction.

According to another aspect of the inventive concept, a vertical memory device includes a substrate; a first interlayer insulating layer on the substrate; a plurality of first bit lines disposed on the first interlayer insulating layer and extending in parallel to each other along a first horizontal direction; an etch stop layer on the plurality of first bit lines; a stack structure disposed on the etch stop layer and comprising a plurality of isolation insulating layers and a plurality of word line plates which are alternately stacked along a vertical direction; and a plurality of electrode structures disposed on the substrate. Each of the plurality of electrode structures includes a single-crystal silicon filler disposed on the substrate and extending along the vertical direction, penetrating the stack structure, the etch stop layer, the plurality of first bit lines, and the first interlayer insulating layer along the vertical direction, and contacting the substrate; and a plurality of variable resistance layers spaced apart from each other along the vertical direction, partially covering a sidewall of the single-crystal silicon filler, and respectively disposed between the single-crystal silicon filler and the plurality of word line plates, and the vertical memory device further comprises a plurality of second bit lines disposed on the plurality of electrode structures and extending along a second horizontal direction orthogonal to the first horizontal direction.

### BRIEF DESCRIPTION OF THE DRAWINGS

Embodiments of the inventive concept will be more clearly understood from the following detailed description taken in conjunction with the accompanying drawings in which:

FIG. 1 is a plan view of a vertical memory device according to embodiments;

FIG. 2 is a cross-sectional view of the vertical memory device, taken along a line Y1-Y1′ of FIG. 1;

FIG. 3 is an enlarged view of a region EX1 of FIG. 2;

FIGS. 4A, 4B and 4C are cross-sectional views illustrating vertical memory devices according to some embodiments;

FIG. 5 is a cross-sectional view of a vertical memory device according to some embodiments;

FIG. 6 is a cross-sectional view of a vertical memory device according to some embodiments; and

FIGS. 7A, 7B, 8A, 8B, 9A, 9B, 10A, 10B, 11A, 11B, 12A, 12B and 13 are plan views and cross-sectional views illustrating a method of manufacturing a vertical memory device according to embodiments. FIGS. 7A, 8A, 9A, 10A, 11A, and 12A are plan views of an order of processes performed on a region corresponding to FIG. 1, and FIGS. 7B, 8B, 9B, 10B, 11B, 12B, and 13 are cross-sectional views of an order of processes performed on a portion taken along the line Y1-Y1′ of FIG. 1.

### DETAILED DESCRIPTION OF THE EMBODIMENTS

Hereinafter, one or more embodiments of the inventive concept will be described in detail with reference to the attached drawings. To the extent that an element has not been described in detail, it may be assumed that the element is at least similar to corresponding elements that have been described in previous figures.

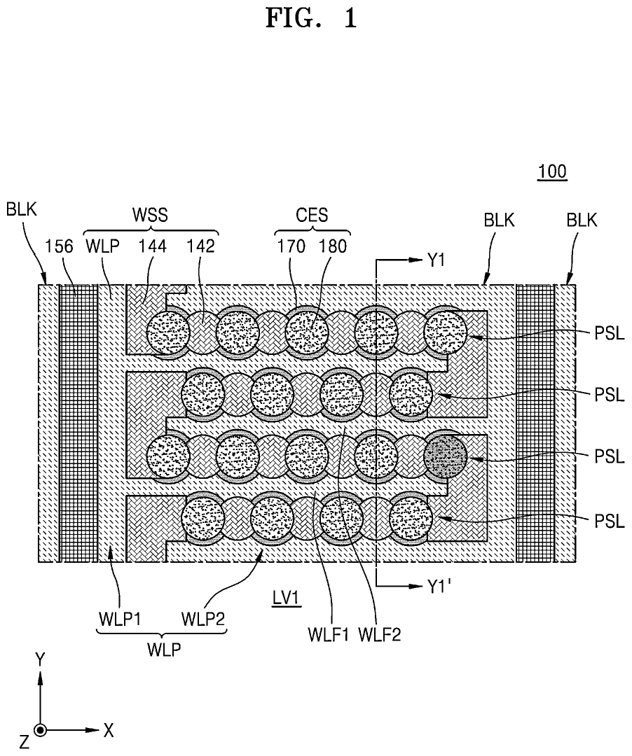

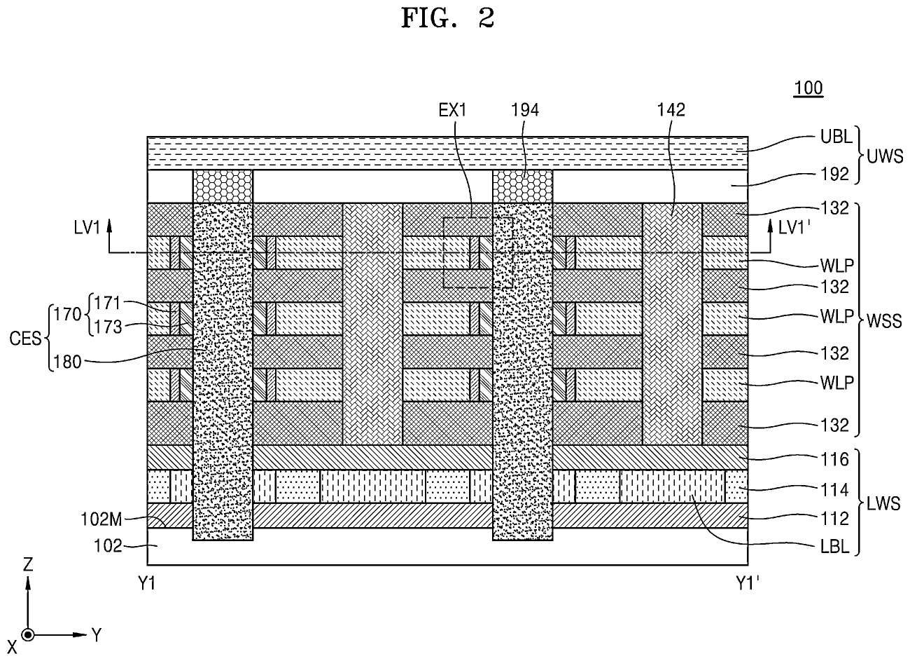

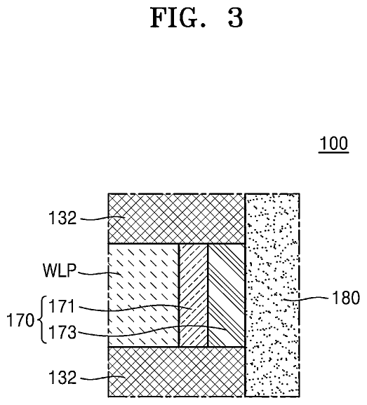

FIG. 1 is a plan view of a vertical memory device 100 according to embodiments. FIG. 2 is a cross-sectional view of the vertical memory device 100, taken along a line Y1-Y1′ of FIG. 1; FIG. 3 is an enlarged view of a region EX1 of FIG. 2. In detail, FIG. 1 is a plan view of the vertical memory device 100 at a first vertical level LV1 of FIG. 2.

Referring to FIGS. 1 to 3, the vertical memory device 100 may include a plurality of cell blocks BLK distinguished by word line cuts 156. In each memory cell block BLK, the vertical memory device 100 may include a substrate 102, a lower wiring structure LWS and a plurality of electrode structures CES on the substrate 102, a stack structure WSS at least partially surrounding the electrode structures CES and disposed on the lower wiring structure LWS, and an upper wiring structure UWS.

According to embodiments, the electrode structures CES may be spaced apart from each other along a first horizontal direction (an X direction) and a second horizontal direction (a Y direction) and may be repeatedly arranged. The electrode structures CES may include conductive fillers 180 respectively extending along a vertical direction (a Z direction) and a plurality of variable resistance layers 170 that at least partially surround sidewalls of the conductive fillers 180 and are spaced apart from each other along the vertical direction (the Z direction). For example, a variable resistance layer 170 may be disposed on and below another variable resistance layer 170. In the present specification, a direction parallel to a main surface 102M of the substrate 102 may be defined as the horizontal direction (the X direction and/or the Y direction), and a direction perpendicular to the horizontal direction (the X direction and/or the Y direction) may be referred to as the vertical direction (the Z direction).

In some embodiments, the substrate 102 may include silicon (Si), such as single crystalline Si, polycrystalline Si (polysilicon), or amorphous Si, but one or more embodiments are not necessarily limited thereto. For example, the substrate 102 may include a group IV semiconductor, such as germanium (Ge), a group IV-IV compound semiconductor, such as silicon germanium (SiGe) or silicon carbide (SiC), or a group III-V compound semiconductor, such as gallium arsenide (GaAs), indium arsenide (InAs), or indium phosphide (InP).

In some embodiments, the substrate 102 may be based on a Si bulk substrate. Additionally, the substrate 102 may be based on a silicon-on-insulator (SOI) substrate or a germanium-on-insulator (GeOI) substrate. However, the substrate 102 is not necessarily limited to the bulk substrate, the SOI substrate, and/or the GeOI substrate and may also be based on an epitaxial wafer, a polished wafer, an annealed wafer, and/or the like. The substrate 102 may include conductive regions, such as wells doped with impurities or various structures doped with impurities. In addition, the substrate 102 may include a P-type substrate or an N-type substrate depending on the types of impurity ions doped. In some regions of the substrate 102, a peripheral circuit and a wiring layer connected to the peripheral circuit may be arranged.

According to embodiments, the stack structure WSS may include a plurality of isolation insulating layers 132 and a plurality of word line plates WLP which are alternately stacked on the lower wiring structure LWS along the vertical direction (the Z direction), a plurality of first insulating blocks 142, a plurality of second insulating blocks 144, and the word line cut structure 156.

As shown in FIG. 2, a lower surface and an upper surface of each word line plate WLP may be covered by the isolation insulating layer 132. In the present specification, the lower surface of each word line plate WLP refers to a surface facing the substrate 102, and the upper surface of each word line plate WLP refers to a surface opposite to the lower surface.

According to embodiments, the variable resistance layers 170 may be arranged one by one between the conductive filler 180 and one of the word line plates WLP. The variable resistance layers 170 included in one electrode structure CES may be spaced apart from and overlap each other in the vertical direction (the Z direction). Each variable resistance layer 170 may contact a sidewall of one of the word line plates WLP and a sidewall of the conductive filler 180. For example, each variable resistance layer 170 may be positioned at the same vertical level as its corresponding word line plate WLP among the word line plates WLP. The term “vertical level” used herein refers to a distance extending along the main surface 102M of the substrate 102 in the vertical direction (the Z direction or the −Z direction). For example, a top surface of the variable resistance layer 170 may be horizontally aligned at a same level with a top surface of the corresponding word line plate WLP.

According to embodiments, the conductive filler 180 of each electrode structure CES may include portions surrounded by the isolation insulating layers 132. According to embodiments, some of the isolation insulating layers 132 may be individually disposed between the variable resistance layers 170. For example, the isolation insulating layers 132 may at least partially overlap the variable resistance layer 170 along the vertical direction (the Z direction). For example, the variable resistance layers 170 may be spaced apart from each other in the vertical direction (the Z direction) with respective isolation insulating layers 132 therebetween.

In some embodiments, the word line plates WLP may each include a doped polysilicon layer, a metal layer, or a combination thereof. For example, the word line plates WLP may each include tungsten (W), but one or more embodiments are not necessarily limited thereto. In some embodiments, the isolation insulating layers 132 may each include at least one selected from among silicon oxide, silicon nitride, and silicon oxynitride, but one or more embodiments are not necessarily limited thereto.

Referring to FIGS. 2 and 3, each variable resistance layer 170 may include a first carbon layer 171 in contact with a corresponding word line plate WLP among the word line plates WLP, and a switching material layer 173 separated from the corresponding word line plate WLP with the first carbon layer 171 therebetween. According to embodiments, one sidewall of the switching material layer 173 may face the corresponding word line plate WLP with the first carbon layer 171 therebetween, and the other sidewall of the switching material layer 173 may face the conductive filler 180. In some embodiments, the switching material layer 173 may contact the conductive filler 180. The first carbon layer 171 of the variable resistance layer 170 may prevent a material forming the word line plates WLP, such as metal atoms, from migrating to the switching material layer 173. Thus, the first carbon layer 171 may prevent the performance degradation in the vertical memory device 100.

According to embodiments, the switching material layer 173 may be an ovonic threshold switching (OTS) material layer and function as a self-selective storage device. Here, the self-selective storage device may refer to a device capable of functioning as both a selective device and a storage device. Depending on the characteristics of the switching material layer 173, the vertical memory device 100 according to embodiments may be referred to as a selector only memory (SOM) device. In the present specification, the switching material layer 173 may be referred to as an OTS material layer.

The switching material layer 173 may include a chalcogenide material, for example, a chalcogenide alloy and/or glass, which functions as a self-selective storage device. The switching material layer 173 may respond to an applied voltage, such as, a program pulse. For example, when applied with a voltage lower than a threshold voltage, the switching material layer 173 may be maintained in an electrically non-conductive state, that is, an “off” state. For example, when applied with a voltage higher than the threshold voltage, the state of the switching material layer 173 may change to an electrically conductive state, that is, an “on” state. The threshold voltage of the switching material layer 173 may be modified according to the polarity of the applied voltage, for example, the polarity of the program pulse. Therefore, in the vertical memory device 100 according to the present embodiment, a bipolar voltage may be used to drive the memory device.

In some embodiments, the switching material layer 173 may include a chalcogenide material of which the phase does not change during operation. The switching material layer 173 may be a layer or layers including a material selected from among two-component materials such as GeSe, GeS, AsSe, AsTe, AsS, SiTe, SiSe, SiS, GeAs, SiAs, SnSe, and SnTe, three-component materials including GeAsTe, GeAsSe, AlAsTe, AlAsSe, SiAsSe, SiAsTe, GeSeTe, GeSeSb, GaAsSe, GaAsTe, InAsSe, InAsTe, SnAsSe, and SnAsTe, four-component materials such as GeSiAsTe, GeSiAsSe, GeSiSeTe, GeSeTeSb, GeSiSeSb, GeSiTeSb, GeSeTeBi, GeSiSeBi, GeSiTeBi, GeAsSeSb, GeAsTeSb, GeAsTeBi, GeAsSeBi, GeAsSeIn, GeAsSeGa, GeAsSeAl, GeAsSeTl, GeAsSeSn, GeAsSeZn, GeAsTeIn, GeAsTeGa, GeAsTeAl, GeAsTeTl, GeAsTeSn, and GeAsTeZn, five-component materials such as GeSiAsSeTe, GeAsSeTeS, GeSiAsSeS, GeSiAsTeS, GeSiSeTeS, GeSiAsSeP, GeSiAsTeP, GeAsSeTeP, GeSiAsSeIn, GeSiAsSeGa, GeSiAsSeAl, GeSiAsSeTl, GeSiAsSeZn, GeSiAsSeSn, GeSiAsTeIn, GeSiAsTeGa, GeSiAsTeAl, GeSiAsTeTl, GeSiAsTeZn, GeSiAsTeSn, GeAsSeTeIn, GeAsSeTeGa, GeAsSeTeAl, GeAsSeTeTl, GeAsSeTeZn, GeAsSeTeSn, GeAsSeSIn, GeAsSeSGa, GeAsSeSAl, GeAsSeSTl, GeAsSeSZn, GeAsSeSSn, GeAsTeSIn, GeAsTeSGa, GeAsTeSAl, GeAsTeSTl, GeAsTeSZn, GeAsTeSSn, GeAsSeInGa, GeAsSeInAl, GeAsSeInTl, GeAsSeInZn, GeAsSeInSn, GeAsSeGaAl, GeAsSeGaTl, GeAsSeGaZn, GeAsSeGaSn, GeAsSeAlTl, GeAsSeAlZn, GeAsSeAlSn, GeAsSeTlZn, GeAsSeTlSn, and GeAsSeZnSn, and six-component materials such as GeSiAsSeTeS, GeSiAsSeTeIn, GeSiAsSeTeGa, GeSiAsSeTeAl, GeSiAsSeTeTl, GeSiAsSeTeZn, GeSiAsSeTeSn, GeSiAsSeTeP, GeSiAsSeSIn, GeSiAsSeSGa, GeSiAsSeSAl, GeSiAsSeSTl, GeSiAsSeSZn, GeSiAsSeSSn, GeAsSeTeSIn, GeAsSeTeSGa, GeAsSeTeSAl, GeAsSeTeSTl, GeAsSeTeSZn, GeAsSeTeSSn, GeAsSeTePIn, GeAsSeTePGa, GeAsSeTePAl, GeAsSeTePTl, GeAsSeTePZn, GeAsSeTePSn, GeSiAsSeInGa, GeSiAsSeInAl, GeSiAsSeInTl, GeSiAsSeInZn, GeSiAsSeInSn, GeSiAsSeGaAl, GeSiAsSeGaTl, GeSiAsSeGaZn, GeSiAsSeGaSn, GeSiAsSeAlSn, GeAsSeTeInGa, GeAsSeTeInAl, GeAsSeTeInTl, GeAsSeTeInZn, GeAsSeTeInSn, GeAsSeTeGaAl, GeAsSeTeGaTl, GeAsSeTeGaZn, GeAsSeTeGaSn, GeAsSeTeAlSn, GeAsSeSInGa, GeAsSeSInAl, GeAsSeSInTl, GeAsSeSInZn, GeAsSeSInSn, GeAsSeSGaAl, GeAsSeSGaTl, GeAsSeSGaZn, GeAsSeSGaSn, and GeAsSeSAlSn. In some embodiments, the switching material layer 173 may include at least one material selected from among the aforementioned two-component to six-component materials and at least one additional element selected from among Boron (B), Carbon (C), Nitrogen (N), and Oxygen (O). In some embodiments, the switching material layer 173 may include glass or amorphous chalcogenide. The terms such as “GeSe,” “GeAsTe,” “GeSiAsTe,” “GeSiAsSeTe,” and “GeSiAsSeTeS” used in the specification refer to materials including elements included in each term and do not represent chemical formulas indicating stoichiometric relationships.

According to embodiments, the lower wiring structure LWS may include a first interlayer insulating layer 112 on the substrate 102, a plurality of lower bit lines LBL disposed on the first interlayer insulating layer 112, a first insulating plate 114 filling a space between the lower bit lines LBL at a vertical level at which the lower bit lines LBL are arranged, and an etch stop layer 116 on the lower bit lines LBL. For example, the first insulating plate 114 may at least partially surround the lower bit lines LBL. In some embodiments, the etch stop layer 116 may be arranged between the lower bit lines LBL and the stack structure WSS. For example, the lowermost word line plate WLP among the word line plates WLP may be spaced apart from the lower bit lines LBL along the vertical direction (the Z direction) with the etch stop layer 116 therebetween. In some embodiments, the lower bit lines LBL may be spaced apart from each other along the second horizontal direction (the Y direction) with the first insulating plate 114 therebetween and may extend in parallel to each other along the first horizontal direction (the X direction).

According to embodiments, the conductive filler 180 of each electrode structure CES may penetrate the lower wiring structure LWS along the vertical direction (the Z direction) and contact the substrate 102. In some embodiments, the conductive filler 180 may include a portion extending into the substrate 102.

In some embodiments, the conductive filler 180 of each electrode structure CES may contact and be connected to one of the lower bit lines LBL.

Referring to FIG. 1, the electrode structures CES may include a plurality of electrode structure lines PSL including the electrode structures CES respectively arranged along the first horizontal direction (the X direction). The electrode structure line PSL may individually and vertically overlap the lower bit lines LBL. In some embodiments, the conductive fillers 180 of each electrode structure line PSL may penetrate and contact a lower bit line LBL. For example, the conductive fillers 180 of the first-group electrode structure CES arranged in a straight line along the first horizontal direction (the X direction) among the electrode structures CES may contact a first lower bit line LBL among the lower bit lines LBL and be connected thereto.

In some embodiments, the etch stop layer 116 may include a material different from that of the isolation insulating layer 132. In some embodiments, the etch stop layer 116, the first interlayer insulating layer 112, and the first insulating plate 114 may include at least one selected from among silicon oxide, silicon nitride, and silicon oxynitride, but one or more embodiments are not necessarily limited thereto. In some embodiments, the lower bit lines LBL may include a conductive material, for example, a doped polysilicon layer, a metal layer, or a combination thereof. For example, the word line plates WLP may include W, but one or more embodiments are not necessarily limited thereto.

In some embodiments, the substrate 102 may include single-crystal silicon. In some embodiments, the substrate 102 may include multiple layers and the upper layer adjacent to the main surface 102M of the substrate 102 may include single-crystal silicon.

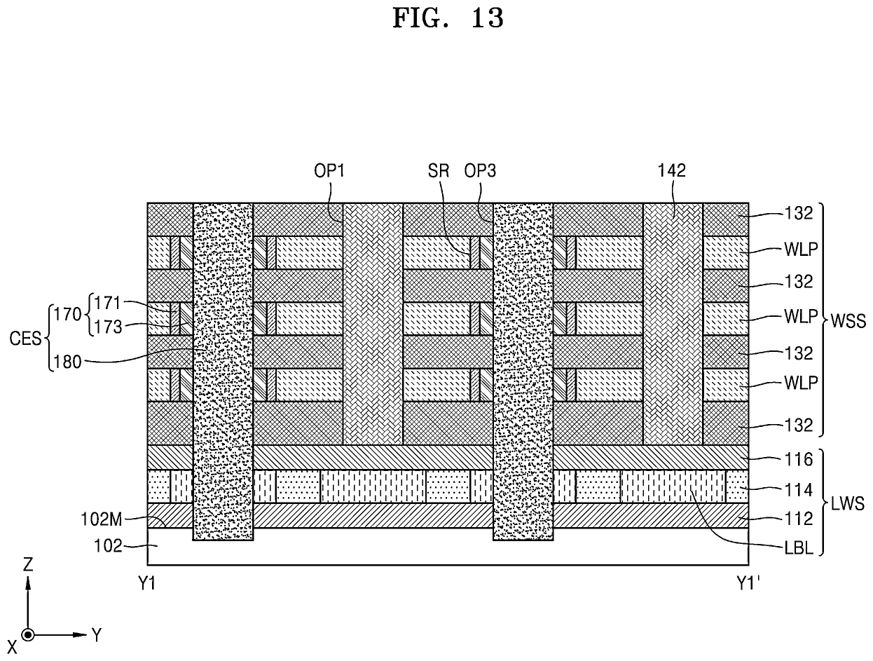

In some embodiments, the substrate 102 and the conductive filler 180 may include the same material, for example, single-crystal silicon. In some embodiments, the conductive filler 180 may include single-crystal silicon grown and/or formed from the substrate 102 which also includes the single-crystal silicon, and the substrate 102 and the conductive filler 180 may form an integral structure. In some embodiments, the conductive filler 180 may include single-crystal silicon formed from polysilicon through a catalyst under low-temperature conditions after filling, with polysilicon, a third opening OP3 (see FIG. 13B) vertically penetrating the stack structure WSS and exposing the substrate 102. The process of forming the single-crystal silicon may be performed at a temperature of less than about 600° C., for example, in a range of about 300° C. to about 500° C. Accordingly, under relatively low temperature conditions, the deformation and/or damage to the variable resistance layer 170 may be prevented by forming the conductive filler 180. In the present specification, the conductive filler 180 may be referred to as a single-crystal silicon filler.

According to embodiments, the first insulating blocks 142 and the second insulating blocks 144 disposed on the lower wiring structure LWS may extend along the vertical direction (the Z direction).

According to embodiments, each first insulating block 142 may be arranged between two electrode structures CES that are adjacent to each other along the first horizontal direction (the X direction). For example, the two electrode structures CES may be spaced apart from each other along the first horizontal direction (the X direction) with a first insulating block 142. In some embodiments, some of the first insulating blocks 142 and some of the electrode structures CES may be alternately arranged along the first horizontal direction (the X direction). In some embodiments, the first insulating blocks 142 may be individually arranged between the electrode structures CES of each electrode structure line PSL. In some embodiments, the conductive filler 180 of respective electrode structures CES may contact side walls of each the first insulating blocks 142 while arranged along the first horizontal direction (the X direction).

In some embodiments, the electrode structure lines PSL may be spaced apart from each other along the second horizontal direction (the Y direction). Two adjacent electrode structure lines PSL disposed along the second horizontal direction (the Y direction) may be alternately arranged so that the electrode structures CES are not arranged in a straight line along the second horizontal direction (the Y direction). For example, in the plan view, the electrode structures CES may be arranged in a honeycomb array and/or a hexagonal array. In some embodiments, in the plan view, the electrode structures CES may be arranged in a matrix form, but a planar arrangement of the electrode structures CES is not necessarily limited thereto.

In some embodiments, the first insulating blocks 142 disposed on the lower wiring structure LWS may be spaced apart from each other along the first horizontal direction (the X direction) and the second horizontal direction (the Y direction). In some embodiments, individual conductive fillers 180 may be arranged between first-group first insulating blocks 142 arranged along the first horizontal direction (the X direction) among the first insulating blocks 142. In some embodiments, each of the first insulating blocks 142 may have sidewalls arranged along the first horizontal direction (the X direction), the sidewalls respectively contacting the conductive filler 180.

According to embodiments, the second insulating blocks 144 may be spaced apart from the word line cut structure 156 which is disposed adjacent to boundaries of respective cell blocks BLK. In some embodiments, the word line cut structure 156 may extend along the second horizontal direction (the Y direction) in the plan view, and the cell blocks BLK that are adjacent to each other along the first horizontal direction (the X direction) may be spaced apart from each other with the word line cut structure 156 therebetween. The cell blocks BLK may extend along the second horizontal direction (the Y direction), and the word line plates WLP may form a stair-shaped pad portion at an edge portion of each cell block BLK along the second horizontal direction (the Y direction). For example, at the aforementioned edge portion of each cell block BLK, a plurality of vertical contacts may be connected to the word line plates WLP arranged at each vertical level through the pad portion, and a voltage may be applied to the word line plates WLP at each level through the vertical contacts.

According to embodiments, each second insulating block 144 may at least partially cover an end portion of each of two electrode structure lines PSL that are adjacent to each other along the second horizontal direction (the Y direction), wherein the end portion extends along the first horizontal direction (the X direction). Here, the end portion refers to an electrode structure CES that is the first or last one in the first horizontal direction (the X direction) among the electrode structures CES forming the electrode structure line PSL. Each of the second insulating blocks 144 may contact two electrode structures CES. For example, each second insulating block 144 may have a width along the second horizontal direction (the Y direction) and cover two electrode structures CES that are adjacent to each other along the second horizontal direction (the Y direction).

According to embodiments, the second insulating blocks 144 may include a first group and a second group that is spaced apart from the first group along the first horizontal direction (the X direction) with the electrode structures CES therebetween. The first group and the second group may be alternately arranged along the first horizontal direction (the X direction). For example, the second insulating blocks 144 may be arranged in a zigzag form along the first horizontal direction (the X direction). In some embodiments, an end portion of each electrode structure line PSL may contact one of the second insulating blocks 144 in the first group, and the other end of each electrode structure line PSL may contact one of the second insulating blocks 144 in the second group. In some embodiments, an end portion of a first electrode structure line PSL and an end portion of a second electrode structure line PSL that is adjacent to the first electrode structure line PSL along the second horizontal direction (the Y direction) may jointly contact the second insulating block 144 from the above first group. For example, the first electrode structure line PSL may be disposed above the second electrode structure line PSL contacting the same second insulating block 144. In this case, the other end portion of the first electrode structure line PSL and the other end portion of the second electrode structure line PSL may respectively contact two different second insulating blocks 144 that are selected from the second group. The other end portion of a third electrode structure line PSL, which is spaced apart from the second electrode structure line PSL along the second horizontal direction (the Y direction) with the first electrode structure line PSL therebetween, and the other end portion of the first electrode structure line PSL may jointly contact a selected second insulating block 144 from the second group.

In some embodiments, in the plan view, the second insulating block 144 may have an L shape, an L shape rotated 90 degrees, a bilaterally symmetrical L shape, or a bilaterally symmetrical L shape rotated 90 degrees, but the shape is not necessarily limited thereto.

According to embodiments, the word line plate WLP may each include a first segment WLP1 and a second segment WLP2 that are positioned at the same vertical level. In some embodiments, the first segment WLP1 and the second segment WLP2 may be spaced apart from each other along the first horizontal direction (the X direction). The first segment WLP1 may include a plurality of first protruding electrode portions WLF1 extending between the electrode structure lines PSL along the first horizontal direction (the X direction), and the second segment WLP2 may include a plurality of second protruding electrode portions WLF2 extending between the electrode structure lines PSL along the first horizontal direction (the X direction). The first segment WLP1 and the second segment WLP2 may each have a comb shape including the first protruding electrode portions WLF1 and the second protruding electrode portions WLF2 to form, for example, interdigitated electrodes. For example, the first protruding electrode portions WLF1 and the second protruding electrode portions WLF2 may be alternately arranged along the second horizontal direction (the Y direction) with the electrode structure line PSL therebetween, and the first segment WLP1 and the second segment WLP2 may have an interdigitated comb shape. For example, the electrode structure lines PSL, the first insulating blocks 142, and the second insulating blocks 144 may form a partition structure that physically separates the first segment WLP1 and the second segment WLP2 of each word line plate WLP. For example, the electrode structure lines PSL, the first insulating blocks 142, and the second insulating blocks 144 may be disposed between the first segment WLP1 and the second segment WLP2. In the vertical memory device 100 according to the present embodiment, as the word line plates WLP include the first segment WLP1 and the second segment WLP2 that are spaced apart from each other, parasitic capacitance in the word line plates WLP decreases. Thus, the operation speed of the vertical memory device 100 may be improved.

According to embodiments, each of the electrode structures CES may horizontally (the Y direction) contact one of the first protruding electrode portions WLF1 on an end portion of each electrode structure CES, and may contact one of the second protruding electrode portions WLF2 on the other end portion of each electrode structure CES. For example, the conductive filler 180 of each electrode structure CES may face the first protruding electrode portion WLF1 and the second protruding electrode portion WLF2 with the variable resistance layers 170 therebetween. The first protruding electrode portion WLF1 and the second protruding electrode portion WLF2 are positioned at the vertical levels respectively corresponding to the variable resistance layers 170.

According to embodiments, the isolation insulating layers 132 may have substantially the same planar shapes as the word line plates WLP. The isolation insulating layers 132 may contact the conductive filler 180 and include portions vertically overlapping the variable resistance layers 170.

In some embodiments, the first insulating blocks 142 may include concave portions on opposite sides thereof along the first horizontal direction (the X direction). For example, the conductive filler 180 may have a cylindrical shape, and the first insulating blocks 142 may generally have cylindrical shapes but other first insulating blocks 142 may have configurations in which the conductive fillers 180 intrude on opposite sides of the first insulating blocks 142 along the first horizontal direction (the X direction). In some embodiments, each variable resistance layer 170 generally has a hollow cylinder shape but may have a configuration in which opposite sides of the hollow cylinder along the first horizontal direction (the X direction) are interrupted by two first insulating blocks 142 that are respectively arranged on opposite sides of the conductive filler 180. For example, each variable resistance layer 170 may include two elements that are apart from each other along the second horizontal direction (the Y direction) with the conductive filler 180 therebetween. For example, the two elements may each have an arc shape in a plan view. However, one or more embodiments are not necessarily limited thereto, and the horizontal cross-section of each of the conductive filler 180 and first insulating blocks 142 may have an oval shape or a polygonal shape including a rectangular shape, and accordingly, the planar shapes of the two elements of each variable resistance layer 170 may correspond to a portion of the boundary of the conductive filler 180.

In some embodiments, the two elements of each variable resistance layer 170 may be spaced apart from each other along the second horizontal direction (the Y direction) and cover at least a portion of the sidewall of the conductive filler 180. The variable resistance layer 170 may be arranged between the conductive filler 180 and the word line plate WLP arranged at the corresponding vertical level among the word line plates WLP. In some embodiments, one of the two elements of each variable resistance layer 170 may contact one of the first protruding electrode portions WLF1 of the first segment WLP1, and the other thereof may contact a selected one of the second protruding electrode portions WLF2.

According to embodiments, the upper wiring structure UWS may be arranged on the electrode structures CES and the stack structure WSS. The uppermost word line plate WLP among the word line plates WLP may be spaced apart from the upper wiring structure UWS along the vertical direction (the Z direction) with the uppermost one of the isolation insulating layers 132 therebetween. The upper wiring structure UWS may include a plurality of upper contacts 194 respectively contacting the conductive fillers 180 of the electrode structures CES disposed on the electrode structures CES, and a plurality of upper bit lines UBL extending in parallel to each other along the second horizontal direction (the Y direction) and disposed on the upper contacts 194. According to embodiments, the upper contacts 194 may contact one of the upper bit lines UBL and be connected thereto. The upper contacts 194 of the first group, arranged along the second horizontal direction (the Y direction) among the upper contacts 194, may commonly one of the first upper bit lines UBL and be connected thereto. In some embodiments, the upper bit lines UBL may extend in a direction crossing the lower bit lines LBL.

In some embodiments, the upper contacts 194 may be located in the corresponding conductive filler 190 and spaced apart from each other along the first horizontal direction (the X direction) and the second horizontal direction (the Y direction). The upper wiring structure UWS may include a second interlayer insulating layer 192 filling a space between the upper contacts 194. The second interlayer insulating layer 192 may at least partially cover an upper surface of the uppermost isolation insulating layer 132 among the isolation insulating layers 132, upper surfaces of the first insulating blocks 142, upper surfaces of the second insulating blocks 144, and an upper surface of the word line cut structure 156. At the vertical level at which the upper bit lines UBL are arranged, the upper wiring structure UWS may include a second insulating plate that fills a space between the upper bit lines UBL.

In some embodiments, the upper contacts 194 and the upper bit lines UBL may each include a conductive material, such as a doped polysilicon layer, a metal layer, or a combination thereof, but one or more embodiments are not necessarily limited thereto. In some embodiments, the second interlayer insulating layer 192 and the second insulating plate may each include at least one selected from among silicon oxide, silicon nitride, and silicon oxynitride, but one or more embodiments are not necessarily limited thereto.

In some embodiments, the conductive filler 180 of each electrode structure CES may contact and be connected to the substrate 102 on an end portion of the conductive filler 180 along the vertical direction (the Z direction) and contact and be connected to one of the upper contacts 194 disposed on the other end portion of the conductive filler 180. In some embodiments, the lower bit lines LBL may be arranged between the substrate 102 and the lowermost word line plate WLP among the word line plates WLP, and the conductive filler 180 of each electrode structure CES may contact and be connected to a selected one of the lower bit lines LBL. In some embodiments, the conductive filler 180 of each electrode structure CES may be electrically connected to one of the upper bit lines UBL through the upper contact 194 which is connected to the other end portion of the conductive filler 180.

The vertical memory device 100 according to embodiments may include the conductive filler 180 contacting and connected to the substrate 102 The conductive filler 180 may extend along the vertical direction (the Z direction) and contact the switching material layer 173 including the OTS material layer at the vertical level at which each word line plate WLP is arranged. In this case, the conductive filler 180 may include single-crystal silicon grown and/or formed from the substrate 102. A conductive filler 180 of a vertical memory device according to a Comparative Example may include polysilicon or metals. For example, in the vertical memory device according to the Comparative Example, to form the conductive filler 180 including polysilicon, a third opening OP3 (see FIG. 13B) may be filled with a polysilicon material, and then, grains of the polysilicon may be grown and provide conductivity to the polysilicon. The process of growing the grains may be generally performed at a relatively high temperature, for example, about 600° C., and while the conductive filler 180 according to the Comparative Example is formed, a variable resistance layer 130 is exposed to a high temperature of about 600° C. The switching material layer 173 contacting the conductive filler 180 may be deformed and/or damaged at high temperature and lose OTS characteristics. On the other hand, the conductive filler 180 according to embodiments, includes single-crystal silicon grown and/or formed from the substrate 102 through a relatively low-temperature process, thus preventing the deformation and/or damage to the switching material layer 173. In addition, secondary effects from an adjacent conductive filler 180 of single-crystal silicon are reduced, a separate barrier layer may not be formed between the conductive filler 180 and the switching material layer 173, and the switching material layer 173 may directly contact the conductive filler 180. The variable resistance layers 170 according to embodiments may be spaced apart from each other along the vertical direction (the Z direction) with the separate insulating layers 132 on top, thereby blocking diffusion between cells in the vertical direction (the Z direction). Accordingly, the reliability of the vertical memory device 100 may be improved. Furthermore, in the vertical memory device 100 according to the present embodiment, the word line plate WLP includes the first segment WLP1 and the second segment WLP2 that are spaced apart from each other, thereby preventing the performance degradation in the vertical memory device 100 due to parasitic capacitance.

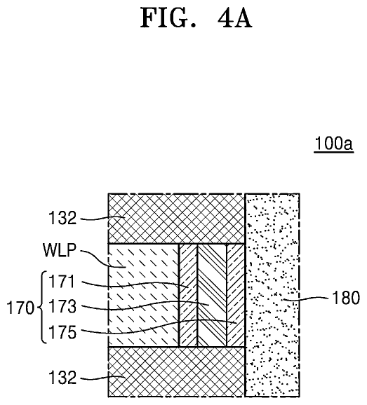

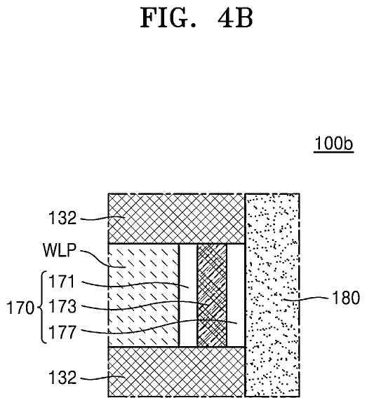

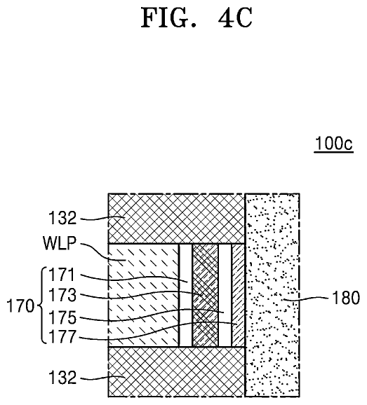

FIG. 4A is a cross-sectional view of a vertical memory device 100a according to some embodiments and an enlarged view showing a portion corresponding to the region EX1 of FIG. 2. In FIG. 4A, to the extent that an element has not been described in detail herein, it may be assumed that the element is at least similar to corresponding elements that have been described in FIGS. 1 to 3.

Referring to FIG. 4A, the vertical memory device 100a may have substantially the same configurations as the vertical memory device 100 of FIGS. 1 to 3. Each of the variable resistance layers 170 of the vertical memory device 100a further includes a second carbon layer 175 arranged between the switching material layer 173 and the conductive filler 180.

According to embodiments, the second carbon layer 175 may contact the conductive filler 180, and the switching material layer 173 may be spaced apart from the conductive filler 180 with the second carbon layer 175 therebetween. For example, the switching material layer 173 may have a structure sandwiched by the first carbon layer 171 and the second carbon layer 175 and may be spaced apart from the conductive filler 180 and the word line plate WLP.

In some embodiments, the second carbon layer 175 may have a shape that is substantially similar to the shapes of the first carbon layer 171 and the switching material layer 173. For example, similar to the description provided for the vertical memory device 100 with reference to FIG. 1, the second carbon layer 175 may include two separated elements having arc shapes. In some embodiments, the second carbon layers 175 of the variable resistance layers 170 may be spaced apart from each other along the vertical direction (the Z direction) and overlap each other. In some embodiments, the upper and lower surfaces of the second carbon layer 175 may be covered by the isolation insulating layers 132, respectively.

FIG. 4B is a cross-sectional view of a vertical memory device 100b according to some embodiments and an enlarged view showing the portion corresponding to the region EX1 of FIG. 2. In FIG. 4B, to the extent that an element has not been described in detail herein, it may be assumed that the element is at least similar to corresponding elements that have been described in FIGS. 1 to 4A.

Referring to FIG. 4B, the vertical memory device 100b may have substantially the same configurations as the vertical memory device 100a of FIG. 4A. The variable resistance layers 170 of the vertical memory device 100b may each include a dielectric layer 177 arranged between the switching material layer 173 and the conductive filler 180 instead of the second carbon layer 175. The dielectric layer 177 of the vertical memory device 100b described with reference to FIG. 4B may have substantially the same structure as the second carbon layer 175 of the vertical memory device 100a described with reference to FIG. 4A. For example, the dielectric layer 177 may contact the conductive filler 180, and the switching material layer 173 may be spaced apart from the conductive filler 180 with the dielectric layer 177 therebetween. The dielectric layers 177 of the variable resistance layers 170 may be spaced apart from each other along the vertical direction (the Z direction) and overlap each other.

In some embodiments, the dielectric layer 177 may include silicon oxide, silicon nitride, silicon oxynitride, or a multilayered oxide/nitride/oxide (ONO) structure.

In some embodiments, the dielectric layer 177 may include at least one material selected from among hafnium oxide (HfO), hafnium silicon oxide (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicon oxide (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), and lead scandium tantalum oxide (PbScTaO). The terms such as “HfO,” ZrO,” “LaO,” “TiO,” “LaO,” and “YO” used in the specification refer to materials containing elements included in each term and do not represent chemical formulas indicating stoichiometric relationships.

In some embodiments, the dielectric layer 177 may include a silicon oxide layer including carbon (C) or hydrocarbon (CxHy). For example, the dielectric layer 177 may include SiOC or SiCOH.

FIG. 4C is a cross-sectional view of a vertical memory device 100c according to some embodiments and an enlarged view showing the portion corresponding to the region EX1 of FIG. 2. In FIG. 4C, to the extent that an element has not been described in detail herein, it may be assumed that the element is at least similar to corresponding elements that have been described in FIGS. 1 to 4B.

Referring to FIG. 4C, the vertical memory device 100c may have substantially the same configurations as the vertical memory devices 100, 100a, and 100b of FIGS. 1 to 4B. For example, the second carbon layer 175 and the dielectric layer 177 may have substantially the same structures as the second carbon layer of the vertical memory device 100a of FIG. 4A and the dielectric layer 177 of the vertical memory device 100b of FIG. 4B, respectively. In the vertical memory device 100c, the second carbon layer 175 and the dielectric layer 177 are respectively arranged between the switching material layer 173 and the conductive filler 180.

In some embodiments, the variable resistance layers 170 may each include the dielectric layer 177, the second carbon layer 175, the switching material layer 173, and the first carbon layer 171 which are sequentially stacked in a direction away from the center of the conductive filler 180. In some embodiments, the dielectric layer 177 may contact the conductive filler 180, cover a portion of the sidewall of the conductive filler 180, and be arranged between the second carbon layer 175 and the conductive filler 180. In some embodiments, the switching material layer 173 may face the conductive filler 180 with the second carbon layer 175 and the dielectric layer 177 therebetween.

In some embodiments, unlike the illustration of FIG. 4C, the arrangement order of the second carbon layer 175 and the dielectric layer 177 of each variable resistance layer 170 may be reversed. For example, the second carbon layer 175 may contact the conductive filler 180, and the dielectric layer 177 may be arranged between the switching material layer 173 and the second carbon layer 175 and may face the conductive filler 180 with the second carbon layer 175 therebetween.

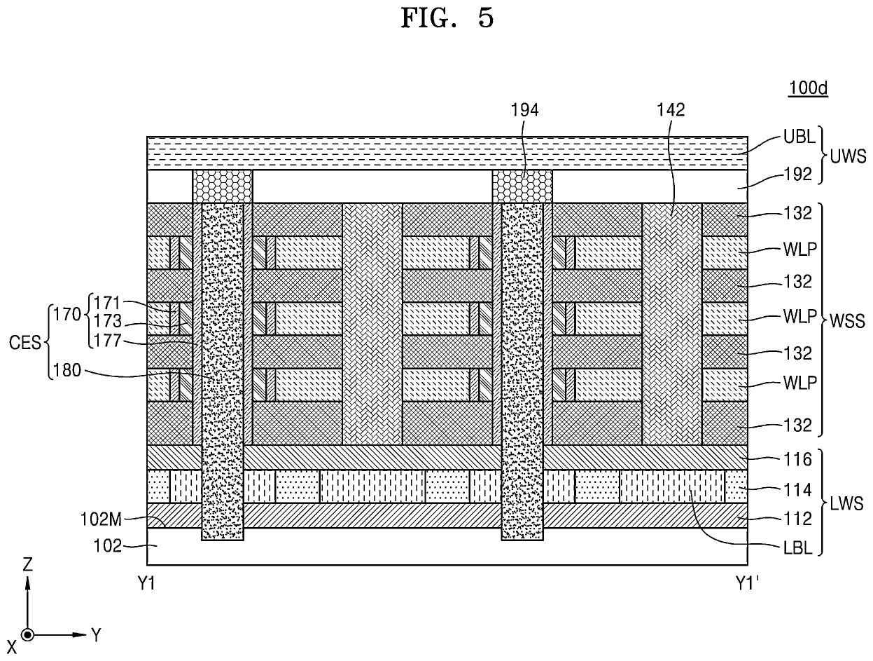

FIG. 5 is a cross-sectional view of a vertical memory device 100d according to some embodiments and shows a portion corresponding to the cross-sectional view taken along a line Y1-Y1′ of FIG. 1. In FIG. 5, to the extent that an element has not been described in detail herein, it may be assumed that the element is at least similar to corresponding elements that have been described in FIGS. 1 to 4C.

Referring to FIG. 5, the vertical memory device 100d may have substantially the same configuration as the vertical memory device 100 of FIGS. 1 to 3. In the vertical memory device 100d, each electrode structure CES on the lower wiring structure LWS may further include a dielectric layer 177 covering the sidewall of the conductive filler 180 and extending along the vertical direction (the Z direction).

According to embodiments, the dielectric layer 177 may be arranged between the conductive filler 180 and the variable resistance layers 170. In some embodiments, the switching material layer 173 of each variable resistance layer 170 may contact the dielectric layer 177 and face the conductive filler 180 with the dielectric layer 177 therebetween. In some embodiments, the dielectric layer 177 may have a hollow cylinder shape in which the conductive filler 180 is located. The dielectric layer 177 may face the word line plates WLP with the variable resistance layers 170 therebetween and contact the first insulating blocks 142, the second insulating blocks 144, and the isolation insulating layers 132. In some embodiments, the lower surface of the dielectric layer 177 may contact the upper surface of the etch stop layer 116. For example, a first portion of the conductive filler 180 that is at a higher vertical level than the upper surface of the etch stop layer 116 may be surrounded by the dielectric layer 177. A second portion of the conductive filler 180 that extends from the first portion to the substrate 102 along the vertical direction (the Z direction) may penetrate the etch stop layer 116, one of the lower bit lines LBL, and the first interlayer insulating layer 112 and contact the substrate 102.

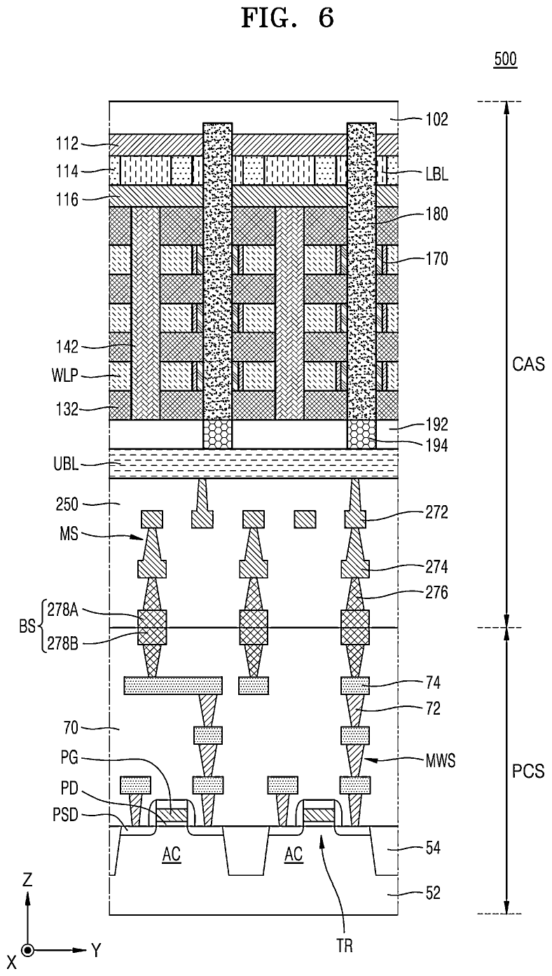

FIG. 6 is a cross-sectional view of a vertical memory device 500 according to some embodiments. In FIG. 6, to the extent that an element has not been described in detail herein, it may be assumed that the element is at least similar to corresponding elements that have been described in FIGS. 1 to 3.

Referring to FIG. 6, the vertical memory device 500 may include a cell array structure CAS and a peripheral circuit structure PCS which overlap each other along the vertical direction (the Z direction). The cell array structure CAS may include a cell block BLK (see FIG. 1) including a plurality of electrode structures CES.

According to embodiments, the vertical memory device 500 may have a chip-to-chip (C2C) structure. The C2C structure may be obtained by forming the cell array structure CAS on a first wafer and the peripheral circuit structure PCS on a second wafer, separate from the first wafer, and then bonding the cell array structure CAS to the peripheral circuit structure PCS. For example, the above bonding process may refer to a method of bonding a plurality of first bonding metal pads 278A, which are formed on the uppermost metal layer of a first multilayered wiring structure MWS1 of the cell array structure CAS, to a plurality of second bonding metal pads 278B, which are formed on the uppermost metal layer of a second multilayered wiring structure MWS2 of the peripheral circuit structure PCS to establish an electrical connection therebetween. In some embodiments, when the first bonding metal pads 278A and the second bonding metal pads 278B each include Cu, the above bonding process may be Cu-Cu bonding. In some embodiments, the first bonding metal pads 278A and the second bonding metal pads 278B may each include Al or W.

The first wafer may be flipped after being manufactured and then bonded to the second wafer. For example, the upper bit lines UBL may be arranged between the electrode structures CES and the peripheral circuit structure PCS. The lower bit lines LBL may be spaced apart from the upper bit lines LBL with the electrode structures CES therebetween at a higher level than the upper bit lines UBL. The substrate 102 of the cell array structure CAS that includes single-crystal silicon may be spaced apart from the peripheral circuit structure PCS along the vertical direction (the Z direction) with the electrode structures CES therebetween.

The peripheral circuit structure PCS may include a substrate 52, a plurality of circuits formed on the substrate 52, and the second multilayered wiring structure MWS2 configured to interconnect the circuits or connect the circuits to components included in the cell block BLK (see FIG. 1) of the cell array structure CAS.

The substrate 52 may be a semiconductor substrate. For example, the substrate 52 may include Si, Ge, or SiGe. In the substrate 52, active areas AC may be defined by a device isolation layer 54. A plurality of transistors TR for forming the circuits may be formed above the active areas AC. Each transistor TR may include a gate dielectric layer PD and a gate PG that are sequentially stacked on the substrate 52, and a plurality of ion implantation areas PSD formed in the active areas AC on both sides of the gate PG. Each ion implantation area PSD may form a source area or a drain area of the transistor TR.

The second multilayered wiring structure MWS2 included in the peripheral circuit structure PCS may include a plurality of contact plugs 72 and a plurality of conductive lines 74. At least some of the conductive lines 74 may be electrically connected to the transistor TR. The contact plugs 72 may be configured to connect the transistors TR to one or more of the conductive lines 74. The transistors TR and the second multilayered wiring structure MWS2 included in the peripheral circuit structure PCS may be at least partially covered by an interlayer insulating layer 70. The interlayer insulating layer 70 may include a silicon oxide layer, a silicon nitride layer, a silicon oxynitride (SiON) layer, a silicon oxycarbonitride (SiOCN) layer, or a combination thereof.

The circuits included in the peripheral circuit structure PCS may further include, for example, unit devices such as resistors and capacitors. The transistors TR, the contact plugs 72, and the conductive lines 74 included in the peripheral circuit structure PCS may form the circuits. Each transistor TR may be electrically connected to a memory cell area MEC through the second multilayered wiring structures MWS2. The upper bit lines UBL may each be connected to the first multilayered wiring structure MWS1. The first multilayered wiring structure MWS1 may include a first upper wire layer 272, a second upper wire layer 274, and a third upper wire layer 276. The first upper wire layer 272, the second upper wire layer 274, and the third upper wire layer 276 may each include W, Ti, Ta, Cu, Al, TiN, TaN, WN, or a combination thereof.

On the upper surface of the cell array structure CAS which is adjacent to the peripheral circuit structure PCS, the first bonding metal pads 278A may be arranged. The upper bit lines UBL may be connected to the first bonding metal pads 278A through the first multilayered wiring structure MWS1. In the cell array structure CAS, the first multilayered wiring structure MWS1 and the first bonding metal pads 278A may be respectively covered by an interlayer insulating layer 250. The interlayer insulating layer 250 may include a silicon oxide layer, a silicon nitride layer, or a combination thereof.

The peripheral circuit structure PCS may include a plurality of second bonding metal pads 278B arranged on the second multilayered wiring structure MWS2. The second bonding metal pads 278B may be connected to the circuits included in the peripheral circuit structure PCS. In the peripheral circuit structure PCS, the interlayer insulating layer 70 may at least partially cover the transistors TR, the contact plugs 72, the conductive lines 74, and the second bonding metal pads 278B.

The second bonding metal pads 278B may be bonded to the first bonding metal pads 278A included in the cell array structure CAS and thus electrically connected thereto. The first bonding metal pads 278A and the second bonding metal pads 278B may form a plurality of bonding structures BS. The lower bit lines LBL may be connected to at least one of the circuits of the peripheral circuit structure PCS through the bonding structures BS including the first bonding metal pads 278A and the second bonding metal pads 278B.

In some embodiments, the contact plugs 72 and the conductive lines 74 included in the peripheral circuit structure PCS may each include W, Al, Cu, or a combination thereof, but one or more embodiments are not necessarily limited thereto. The device isolation layer 54 may include a silicon oxide layer, a silicon nitride layer, or a combination thereof. The interlayer insulating layer 70 may include a silicon oxide layer, a silicon nitride layer, or a combination thereof. The first bonding metal pads 278A and the second bonding metal pads 278B forming the bonding structures BS may each include Cu, Al, or W.

The single-crystal silicon substrate 102 may be at least partially covered by an insulating layer in the cell array structure CAS. The insulating layer may include a silicon oxide layer but is not limited thereto.

Hereinafter, a method of manufacturing a vertical memory device, according to embodiments, is described in detail.

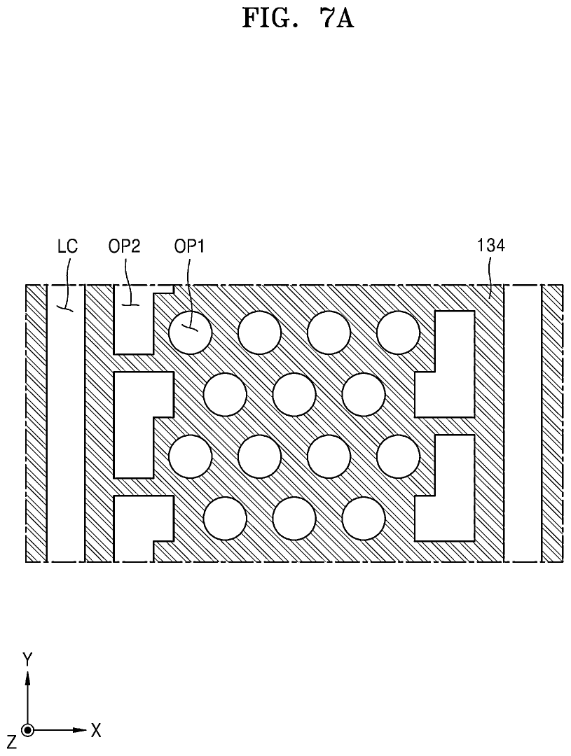

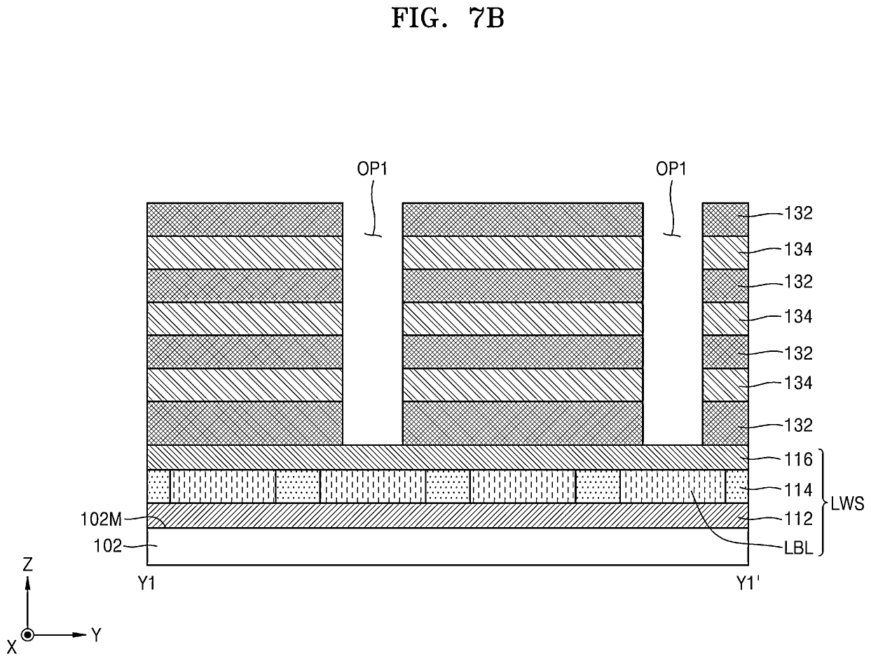

FIGS. 7A to 13 are plan views and cross-sectional views illustrating a method of manufacturing a vertical memory device according to embodiments, wherein FIGS. 7A, 8A, 9A, 10A, 11A, and 12A are plan views of an order of processes performed on a region corresponding to FIG. 1, and FIGS. 7B, 8B, 9B, 10B, 11B, 12B, and 13 are cross-sectional views of an order of processes performed on a portion taken along the line Y1-Y1′ of FIG. 1. To the extent that an element has not been described in detail herein, it may be assumed that the element is at least similar to corresponding elements that have been described in FIGS. 1 to 3.

Referring to FIGS. 7A and 7B, after a lower wiring structure LWS is formed on the substrate 102, a plurality of isolation insulating layers 132 and a plurality of sacrificial layers 134 may be alternately stacked one by one on the lower wiring structure LWS.

In some embodiments, a first interlayer insulating layer 112 may be formed on the substrate 102 including single-crystal silicon, and the lower bit lines LBL may be formed on the first interlayer insulating layer 112. For example, the lower bit lines LBL may be formed by forming the first insulating plate 114 first and removing some portions of the first insulating plate 114 to form a plurality of trenches extending along the first horizontal direction (the X direction) and then filling the trenches with a conductive material and planarizing the trenches so that the upper surface of the first insulating plate 114 is exposed. For example, the lower bit lines LBL may be formed through Physical Vapor Deposition (PVD) or a plating process, but one or more embodiments are not necessarily limited thereto. Then, the etch stop layer 116 covering the upper surface of the first insulating plate 114 and the upper surfaces of the lower bit lines LBL may be formed.

Then, the isolation insulating layers 132 and the sacrificial layers 134 may be alternately stacked one by one on the etch stop layer 116. The isolation insulating layers 132 and the sacrificial layers 134 may each include silicon oxide, silicon nitride, SiON, SiOCN, or a combination thereof. In some embodiments, the isolation insulating layers 132 and the sacrificial layers 134 may have etch selectivity with respect to each other.

Then, as shown in FIGS. 7A and 7B, a plurality of line cuts LC, a plurality of first openings OP1, and a plurality of second openings OP2 penetrating the isolation insulating layers 132 and the sacrificial layers 134 along the vertical direction (the Z direction) and exposing the etch stop layer 116 may be formed. The line cuts LC may be formed at locations corresponding to the word line cut structures 156 of FIG. 1, the first openings OP1 may be formed at locations corresponding to the first insulating blocks 142 described with reference to FIGS. 1 to 3, and the second openings OP2 may be formed at locations corresponding to the second insulating blocks 144.

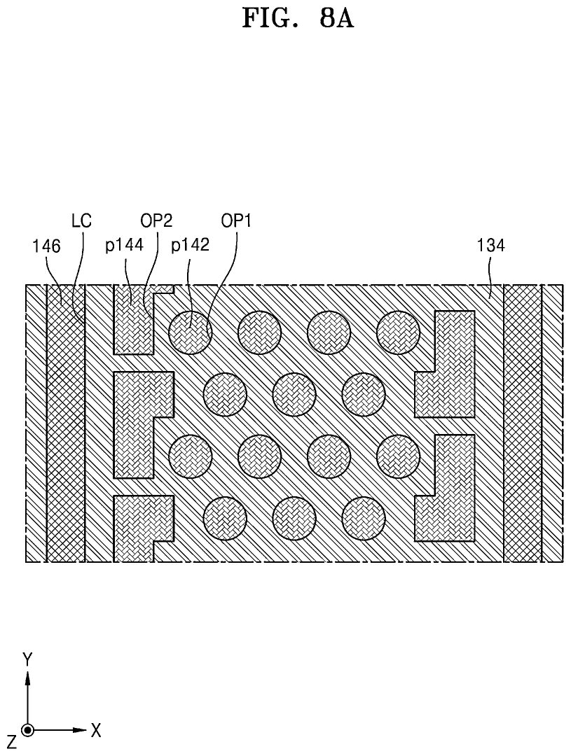

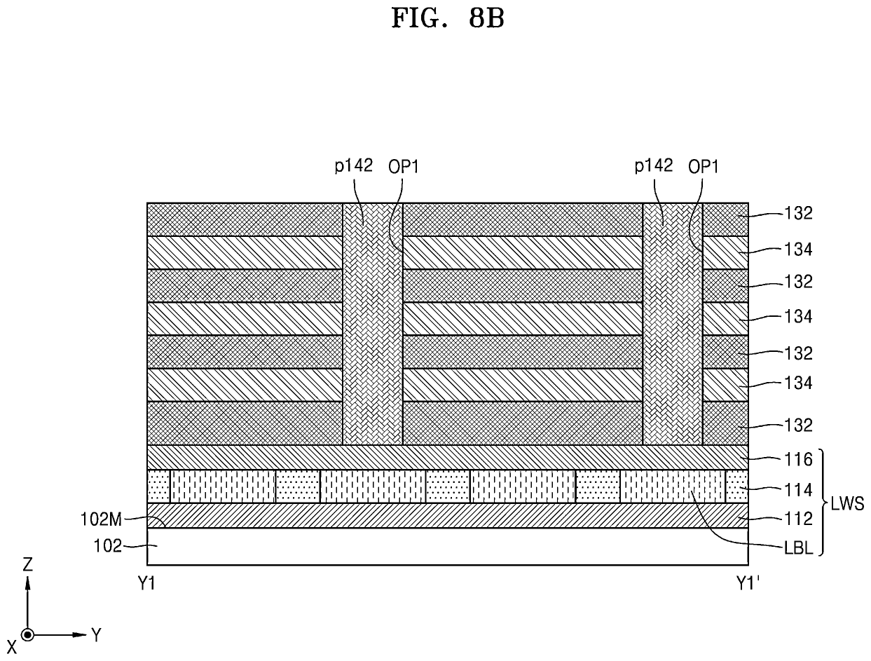

Referring to FIGS. 8A and 8B, a plurality of first insulating fillers p142 filling the first openings OP1, a plurality of second insulating fillers p144 filling the second openings OP2, and a plurality of third insulating fillers 146 filling the line cuts LC may be formed as the result of process shown in FIGS. 7A and 7B. In some embodiments, the first insulating fillers p142, the second insulating fillers p144, and the third insulating fillers 146 may each include silicon oxide, silicon nitride, SiON, SiOCN, or a combination thereof. In some embodiments, the third insulating fillers 146 may include materials different from those of the first insulating fillers p142 and the second insulating fillers p144 and have etch selectivity based on the first insulating fillers p142 and the second insulating fillers p144. In some embodiments, the first insulating fillers p142 and the second insulating fillers p144 may have etch selectivity with respect to the sacrificial layers 134.

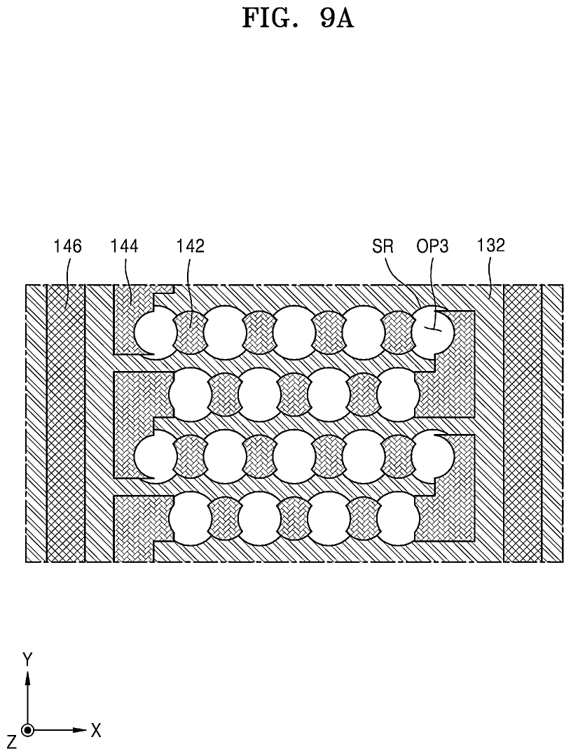

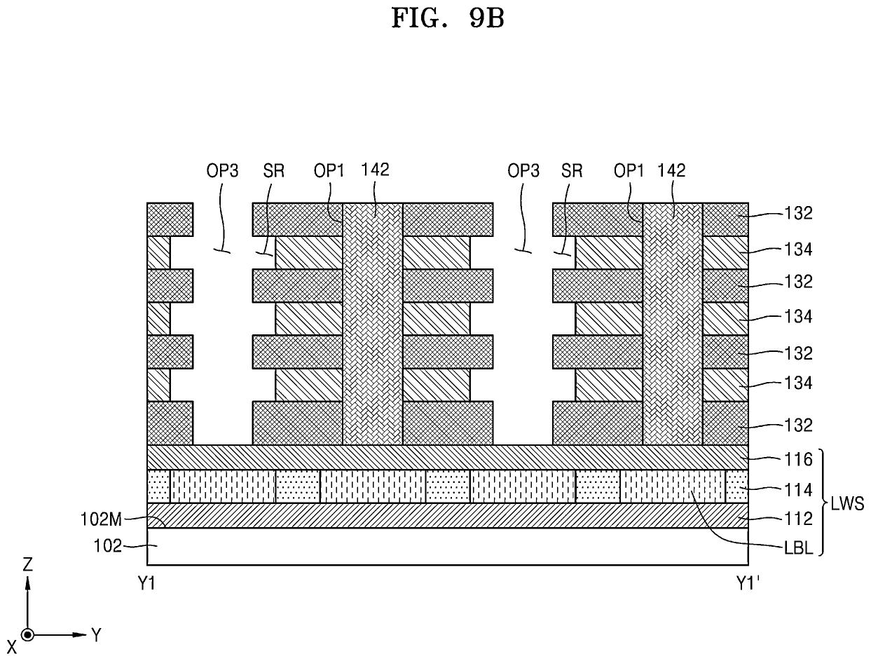

Referring to FIGS. 9A and 9B, in the result of FIGS. 8A and 8B, a plurality of third openings OP3 penetrating the isolation insulating layers 132 and the sacrificial layers 134 along the vertical direction (the Z direction) and exposing the etch stop layer 116 may be formed. During the process of forming the third openings OP3, both side portions of the first insulating fillers p142 along the first horizontal direction (the X direction) may be removed and form the first insulating blocks 142, and some of the second insulating fillers p144 may be removed and form the second insulating blocks 144. In some embodiments, each of the third openings OP3 may be formed at a location corresponding to the conductive filler 180 of each electrode structure CES described with reference to FIG. 1.

Then, by removing part of the inner sidewalls of the sacrificial layers 134 exposed through the third openings OP3, a plurality of indented regions SR respectively connected to the third openings OP3 may be formed.

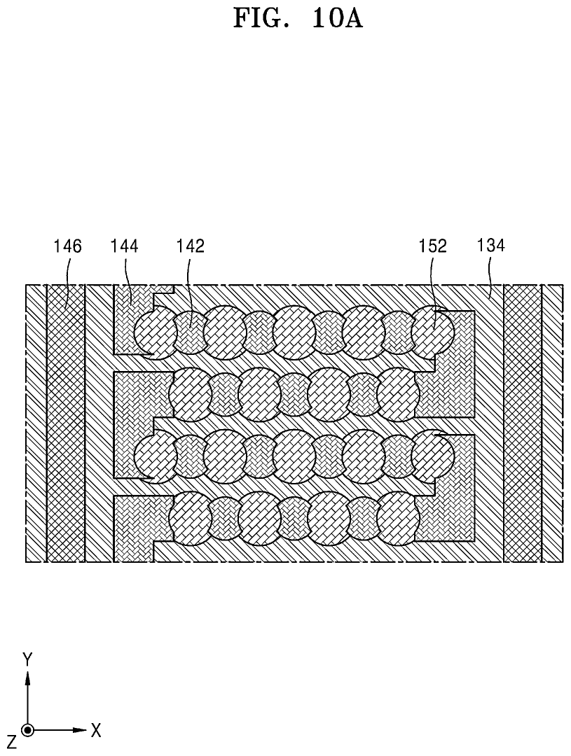

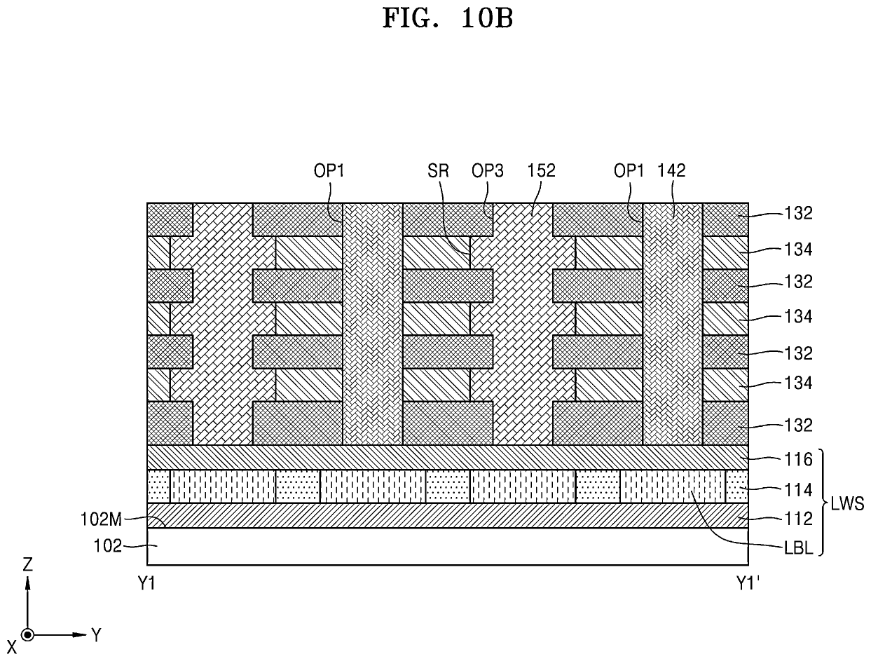

Referring to FIGS. 10A and 10B, in the result of FIGS. 9A and 9B, a plurality of fourth insulating fillers 152 filling the third openings OP3 and the indented regions SR may be formed. In some embodiments, the fourth insulating fillers 152 may each include silicon oxide, silicon nitride, SiON, SiOCN, or a combination thereof. In some embodiments, the fourth insulating fillers 152 may include materials having etch selectivity with respect to the third insulating fillers 146 and the sacrificial layers 134.s

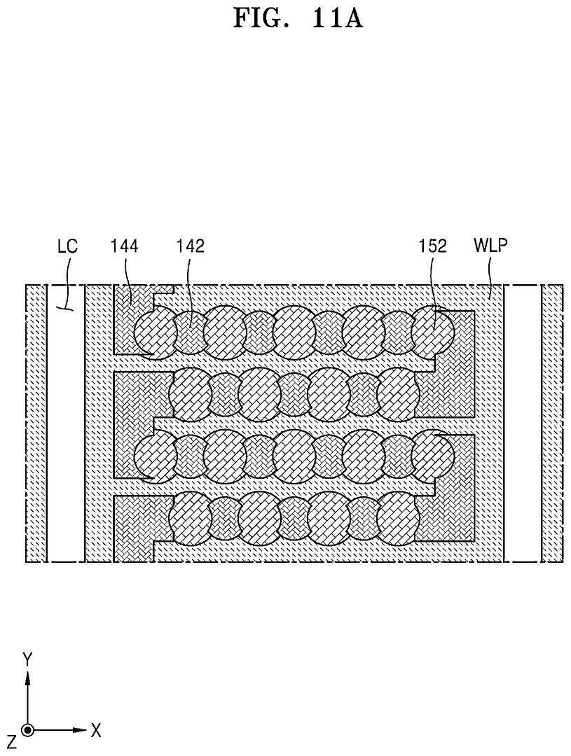

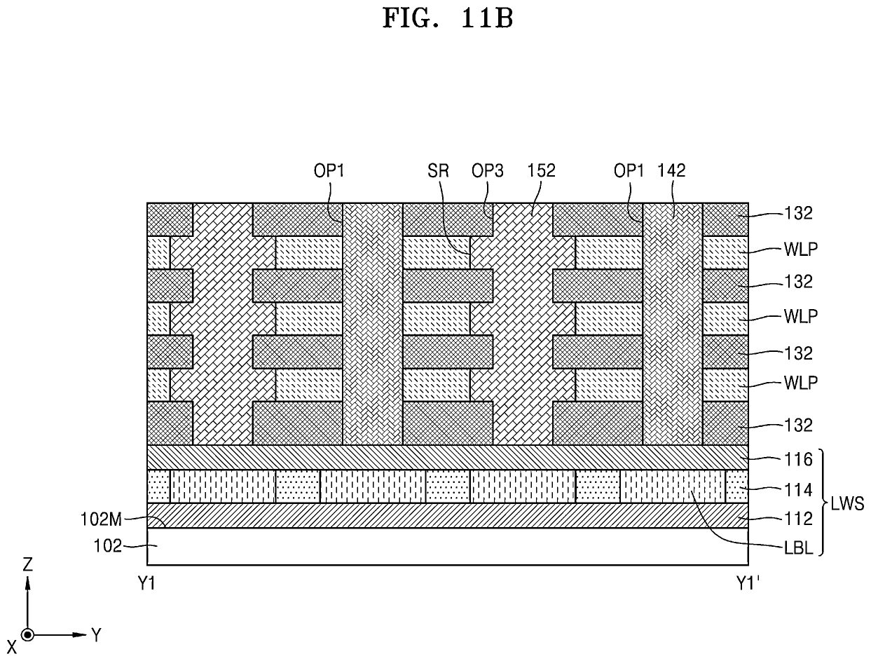

Referring to FIGS. 11A and 11B, in the result of FIGS. 10A and 10B, after the line cuts LC may be opened by removing the third insulating fillers 146, the sacrificial layers 134 exposed through the line cuts LC may be removed. For example, the sacrificial layers 134 may be removed through wet etching. The conductive material may include a doped semiconductor material, metals, conductive metal nitride, conductive metal oxide, or the like, but is not necessarily limited thereto.

Then, after a space, which is formed through the removal of the sacrificial layers 134, and the line cuts LC are filled with the conductive material, the line cuts LC may be formed again, and thus, the word line plates WLP may be formed. For example, the word line plates WLP may be arranged between the isolation insulating layers 132 one by one and may contact protrusions of the fourth insulating fillers 152 that fill the indented regions SR. After the formation of an insulating material layer with a thickness sufficient enough to fill the line cuts LC, the insulating material layer is planarized until the upper surface of each of the first insulating blocks 142, the second insulating blocks 144, and the fourth insulating fillers 152, thereby forming the word line cuts WLC.

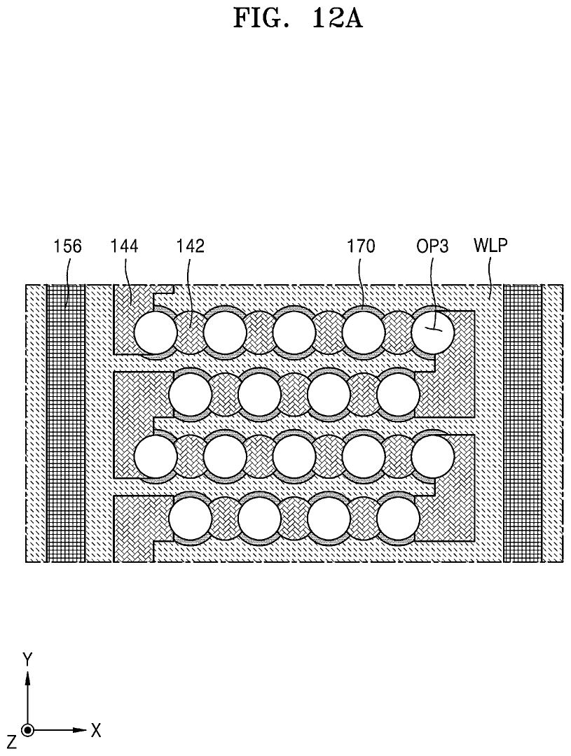

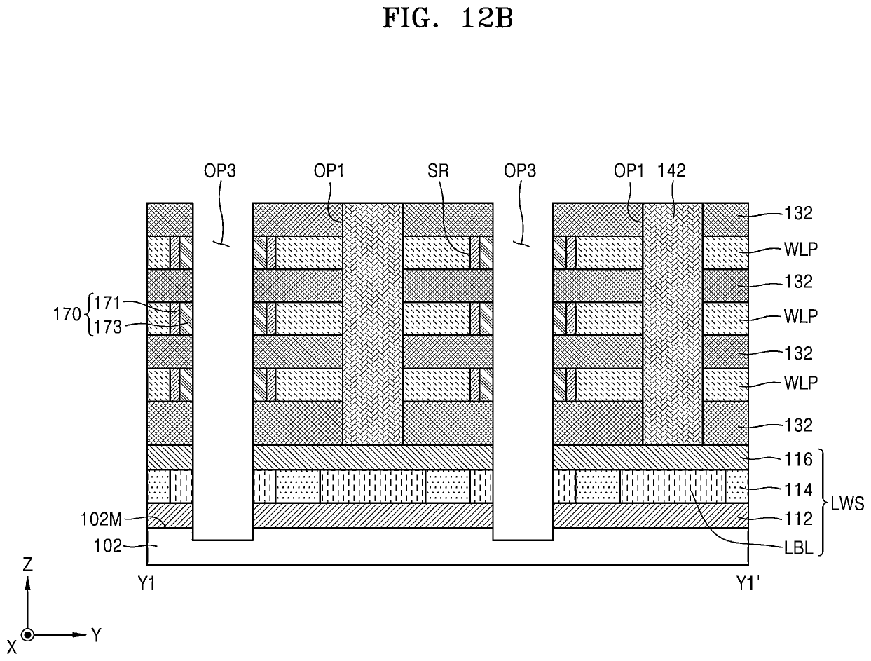

Referring to FIGS. 12A and 12B, in the result of FIGS. 11A and 11B, after the fourth insulating fillers 152 are removed, the variable resistance layers 170 may be formed.

In some embodiments, after the removal of the fourth insulating fillers 152, a carbon material layer filling the indented regions SR and covering inner surfaces of the third openings OP3 is formed and then etched back to form a first carbon layer 171 filling portions of the indented regions SR. Then, an OTS material layer filling the remaining portions of the indented regions SR and covering the inner surfaces of the third openings OP3 is formed and then etched back to form a switching material layer 173 filling the remaining portions of the indented regions SR.

Then, the etch stop layer 116, the lower bit lines LBL, and the first interlayer insulating layer 112 are partially removed through anisotropic etching, and thus, the substrate 102 may be exposed from the lower surface of each third opening OP3.

Referring to FIG. 13, in the result of FIG. 12B, a polysilicon material layer filling at least a portion of the third openings OP3 may be formed. The polysilicon material layer may cover the inner wall of each third opening OP3 and the surface of the substrate 102 exposed through the third openings OP3. Then, the conductive filler 180 including single-crystal silicon may be grown and/or formed from the polysilicon material layer in a relatively low-temperature range, for example, between about 300° C. and about 500° C. According to a method of manufacturing a vertical memory device according to the Comparative Example, a single-crystal silicon material may be epitaxially grown from a single-crystal silicon substrate 102 exposed through third openings OP3. In this case, a relatively high-temperature process of about 600° C. is performed to epitaxially grow the single-crystal silicon material, and thus, the switching material layer 173 may likely be damaged. According to a method of manufacturing the vertical memory device 100 according to an embodiment, the conductive filler 180 including the single-crystal silicon material formed from the substrate 102 may be formed through the relatively low-temperature process. Thus, the damage to and/or deformation of the switching material layer 173 may be prevented such that the reliability of the vertical memory device 100 may be improved.

Referring to FIGS. 13 and 2 together, the second interlayer insulating layer 192 may be formed, the second interlayer insulating layer 192 covering the upper surface of each of the conductive fillers 180 of the electrode structures CES, the uppermost isolation insulating layer 132 among the isolation insulating layers 132, the first insulating blocks 142, the second insulating blocks 144, and the word line cuts WLC. Then, after openings exposing the conductive fillers 180 are formed by removing a portion of the second interlayer insulating layer 192, the upper contacts 194 may be formed by filling the openings with the conductive material. Next, the upper bit lines UBL and a second insulating plate for insulating the upper bit lines UBL from each other may be formed in the upper contacts 194.

While the inventive concept has been particularly shown and described with reference to embodiments thereof, it will be understood that various changes in form and details may be made therein without departing from the spirit and scope of the following claims.

What is claimed is:

1. A vertical memory device comprising:
a substrate;
a stack structure comprising a plurality of isolation insulating layers and a plurality of word line plates which are alternately stacked on the substrate along a vertical direction; and
a plurality of electrode structures disposed on the substrate,
wherein each of the plurality of electrode structures comprises:
a single-crystal silicon filler extending on the substrate along the vertical direction, penetrating the plurality of isolation insulating layers and the plurality of word line plates, and contacting the substrate; and
a plurality of variable resistance layers spaced apart from each other along the vertical direction, and partially covering a sidewall of the single-crystal silicon filler, wherein each variable resistance layer is arranged between the single-crystal silicon filler and two of the word line plates.

2. The vertical memory device of claim 1, wherein the plurality of variable resistance layers comprise an ovonic threshold switching (OTS) material layer.

3. The vertical memory device of claim 1, wherein each of the plurality of variable resistance layers comprises:
a switching material layer contacting a portion of the sidewall of the single-crystal silicon filler; and
a first carbon layer spaced apart from the single-crystal silicon filler with the switching material layer therebetween, and wherein the first carbon layer is disposed between the switching material layer and a corresponding word line plate among the plurality of word line plates.

4. The vertical memory device of claim 1, wherein each of the plurality of variable resistance layers comprises:
a switching material layer;
a first carbon layer disposed between the switching material layer and a corresponding word line plate among the plurality of word line plates; and
a second carbon layer contacting a portion of the sidewall of the single-crystal silicon filler, wherein the second carbon layer is disposed between the switching material layer and the single-crystal silicon filler.

5. The vertical memory device of claim 1, wherein each of the plurality of variable resistance layers comprises:
a switching material layer;
a first carbon layer disposed between the switching material layer and a corresponding word line plate among the plurality of word line plates; and
a dielectric layer contacting a portion of the sidewall of the single-crystal silicon filler, wherein the dielectric layer is disposed between the switching material layer and the single-crystal silicon filler.

6. The vertical memory device of claim 1, further comprising a lower wiring structure disposed between the substrate and the stack structure,
wherein the lower wiring structure comprises:
an interlayer insulating layer disposed on the substrate;
a plurality of first bit lines disposed on the interlayer insulating layer; and
an etch stop layer between the plurality of first bit lines and the stack structure, and
the single-crystal silicon filler penetrates the lower wiring structure along the vertical direction and contacts the substrate.

7. The vertical memory device of claim 6, further comprising a dielectric layer disposed between the plurality of variable resistance layers and the single-crystal silicon filler,
wherein the dielectric layer partially surrounds the sidewall of the single-crystal silicon filler, extends along the vertical direction, and contacts an upper surface of the etch stop layer.

8. The vertical memory device of claim 6, further comprising a plurality of second bit lines disposed on the plurality of electrode structures,
wherein the plurality of second bit lines extend along a direction crossing the plurality of first bit lines.

9. The vertical memory device of claim 1, wherein the single-crystal silicon filler has a cylindrical shape extending along the vertical direction, and
wherein the plurality of variable resistance layers comprise two arc-shaped elements that are spaced apart from each other with the single-crystal silicon filler therebetween.

10. The vertical memory device of claim 1, wherein the substrate comprises single-crystal silicon.

11. A vertical memory device comprising:
a single-crystal silicon substrate;
a plurality of single-crystal silicon fillers that are repeatedly disposed along a first horizontal direction and a second horizontal direction and extend along a vertical direction, wherein an end portion of each of the plurality of single-crystal silicon fillers along the vertical direction is connected to the single-crystal silicon substrate, and wherein the first horizontal direction and the second horizontal direction cross each other;
a plurality of word line plates that are spaced apart from each other on the single-crystal silicon substrate along the vertical direction, overlap each other along the vertical direction, and at least partially surround a portion of a sidewall of each of the plurality of single-crystal silicon fillers; and
a plurality of ovonic threshold switching (OTS) material layers respectively disposed between the plurality of single-crystal silicon fillers and the plurality of word line plates, wherein the OTS material layer are spaced apart from each other along the vertical direction.

12. The vertical memory device of claim 11, wherein each of the plurality of word line plates comprises a first segment and a second segment that are spaced apart from each other along a horizontal direction and positioned at a same vertical level,
wherein the first segment and the second segment have comb shapes each comprising a plurality of protruding electrode portions to form interdigitated electrodes, and
wherein the plurality of single-crystal silicon fillers respectively extend along the vertical direction and are disposed between the plurality of protruding electrode portions of the first segment and the plurality of protruding electrode portions of the second segment.

13. The vertical memory device of claim 12, further comprising a plurality of first insulating blocks respectively arranged between two single-crystal silicon fillers that are adjacent to each other along the first horizontal direction,
wherein the plurality of first insulating blocks respectively extend along the vertical direction and are disposed between the plurality of protruding electrode portions of the first segment and the plurality of protruding electrode portions of the second segment.

14. The vertical memory device of claim 13, further comprising an etch stop layer disposed between the single-crystal silicon substrate and the plurality of word line plates,
wherein the plurality of single-crystal silicon fillers penetrate the etch stop layer and contact the single-crystal silicon substrate, and
wherein the plurality of first insulating blocks contact an upper surface of the etch stop layer.

15. The vertical memory device of claim 13, wherein each of the plurality of single-crystal silicon fillers has a circular planar shape, and
wherein the plurality of first insulating blocks comprise concave portions on opposite sides along the first horizontal direction, wherein the concave portions contact a corresponding single-crystal silicon filler.

16. The vertical memory device of claim 15, wherein each of the plurality of OTS material layers comprises a first element and a second element that are spaced apart from each other and disposed at a same vertical level,
wherein the first element and the second element are spaced apart from each other with a first single-crystal silicon filler and two first insulating blocks therebetween, and
wherein the first element and the second element have arc shapes that face each other.

17. A vertical memory device comprising:
a substrate;
a first interlayer insulating layer on the substrate;
a plurality of first bit lines disposed on the first interlayer insulating layer and extending in parallel to each other along a first horizontal direction;
an etch stop layer on the plurality of first bit lines;
a stack structure disposed on the etch stop layer and comprising a plurality of isolation insulating layers and a plurality of word line plates which are alternately stacked along a vertical direction; and
a plurality of electrode structures disposed on the substrate,
wherein each of the plurality of electrode structures comprises:
a single-crystal silicon filler disposed on the substrate and extending along the vertical direction, penetrating the stack structure, the etch stop layer, the plurality of first bit lines, and the first interlayer insulating layer along the vertical direction, and contacting the substrate; and
a plurality of variable resistance layers spaced apart from each other along the vertical direction, partially covering a sidewall of the single-crystal silicon filler, and respectively disposed between the single-crystal silicon filler and the plurality of word line plates, and
the vertical memory device further comprises a plurality of second bit lines disposed on the plurality of electrode structures and extending along a second horizontal direction orthogonal to the first horizontal direction.

18. The vertical memory device of claim 17, wherein each of the plurality of variable resistance layers comprises:
a switching material layer contacting a portion of the sidewall of the single-crystal silicon filler and comprising an ovonic threshold switching (OTS) material; and
a first carbon layer spaced apart from the single-crystal silicon filler with the switching material layer therebetween and disposed between the switching material layer and a corresponding word line plate among the plurality of word line plates.

19. The vertical memory device of claim 17, wherein the substrate comprises single-crystal silicon.

20. The vertical memory device of claim 17, wherein each of the plurality of word line plates comprises a first segment and a second segment that are spaced apart from each other along a horizontal direction and positioned at a same vertical level,
wherein the first segment and the second segment have comb shapes each comprising a plurality of protruding electrode portions to form interdigitated electrodes, and
wherein the single-crystal silicon filler extends along the vertical direction and is disposed between the plurality of protruding electrode portions of the first segment and the plurality of protruding electrode portions of the second segment.
